(19) United States
(12) Patent Application Publication
(10) Pub. No.: US 2008/0073786 A1
(43) Pub. Date: Mar. 27, 2008

(54) Semiconductor device and method of manufacturing the same

(75) Inventors: Manabu Tanabe, Osaka (JP); Hiroaki Fujimoto, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/902,427

(22) Filed: Sep. 21, 2007

(30) Foreign Application Priority Data
Sep. 22, 2006 (JP) 2006-256550
Aug. 9, 2007 (JP) 2007-207308

(51) Int. Cl. H01L 23/49; H01L 21/60

(52) U.S. Cl. 257/741; 438/109; 257/E21.506; 257/E23.025

(57) ABSTRACT

In a semiconductor device of the present invention, of wires 5a, 5b and 5c which are vertically arranged to connect a plurality of electrodes 3 formed on a major surface of a semiconductor chip 2 and internal electrodes 4 of conductor portions arranged around the semiconductor chip 2, the wires 5a at the lowest level have the lowest stiffness and the wires 5b and 5c at a higher level have higher stiffness. With this configuration, it is possible to eliminate contact among the wires 5a, 5b and 5c, thereby improving the yields.

### FIELD OF THE INVENTION

The present invention relates to a packaged semiconductor device using a semiconductor chip having multiple pins, and relates to a method of manufacturing the same.

### BACKGROUND OF THE INVENTION

In recent years, electronic equipment such as mobile communications equipment has become smaller in size, enhanced in performance, and become more multifunctional. In response to such development, semiconductor devices have been reduced in size and increased in density with a larger number of pins. For example, packaged semiconductor devices having external terminals arranged in area arrays on the undersides have been frequently used. The electrodes of packaged semiconductor chips have been arranged not only in a single row but also in multiple rows such as a staggered arrangement on the peripheries (edges) of the chips.

As an example of such a semiconductor device, a BGA (Ball Grid Array) package is shown in FIGS. 7(A) and 7(B). A semiconductor chip 2 having multiple pins is fixed on a BGA substrate 1 (hereinafter, will be simply referred to as a substrate 1), electrodes 3 of the semiconductor chip 2 and internal electrodes 4 formed on the substrate 1 are electrically connected via bonding wires 5 (hereinafter, will be simply referred to as wires 5), and the semiconductor chip 2 and the wires 5 are covered with a sealing resin 6 by transfer molding and so on. In FIG. 7(B), only some of the wires 5 are shown and the illustration of the sealing resin 6 is omitted.

The electrodes 3 are arranged in multiple rows on the edge of a major surface of the semiconductor chip 2. On the substrate 1, the internal electrodes 4 are formed in multiple rows around the semiconductor chip 2, external electrodes 7 electrically connected to the internal electrodes 4 via through holes and the like are formed in a grid-like fashion and so on, and solder balls 8 are formed on the external electrodes 7.

In such a BGA package, the wires 5 are three-dimensionally arranged for the semiconductor chip 2 having multiple pins. As shown in FIGS. 7(A) and 7(B), wires 5a connected to electrodes 3a in the outermost row on the semiconductor chip 2 are connected to internal electrodes 4a in the innermost row on the substrate 1, and wires 5b and 5c connected to electrodes 3b and 3c disposed inside the electrodes 3a are connected to internal electrodes 4b and 4c disposed outside the internal electrodes 4a. The wires 5a, 5b and 5c are controlled such that the top of the wire 5a is lower than the wire 5b and the top of the wire 5b is lower than the wire 5c (for example, see National Publication of International Patent Application No. 2005-532672).

However, in the case where the wires 5 (5a, 5b and 5c) are three-dimensionally arranged thus, it is difficult to control loops because the wires 5 are made of gold (Au), resulting in contact between the wires 5 and lower yields. Gold is quite an expensive material.

### DISCLOSURE OF THE INVENTION

In view of this problem, an object of the present invention is to eliminate contact between the bonding wires of a semiconductor device using a semiconductor chip having multiple pins, and increase the yields.

In order to attain the object, a semiconductor device of the present invention in which a plurality of electrodes formed on a major surface of a semiconductor chip and the inner terminals of a plurality of conductor portions arranged around the semiconductor chip are electrically connected via thin metal wires and the semiconductor chip and the thin metal wires are sealed with resin, of the plurality of thin metal wires vertically arranged to connect the electrodes of the semiconductor chip and the inner terminals of the conductor portions, the thin metal wires at the lowest level have the lowest stiffness.

With this configuration, the thin metal wires at the lowest level have the lowest stiffness and thus can be reduced in height. Since the thin metal wires at a higher level have higher stiffness, the shapes of the loops can be easily controlled upon bonding. Further, it is possible to suppress deformations on the loops after bonding and suppress deformations caused by stresses generated by a resin flow during resin sealing. Thus a desired height and shape can be kept. It is therefore possible to avoid contact between the thin metal wires, improving the yields.

For example, the semiconductor chip may have first electrodes arranged in rows on the periphery of the major surface and second electrodes arranged at least in a single row closer to the center of the major surface than the first electrodes, the first electrodes of the semiconductor chip and the inner terminals of the conductor portions may be connected via first thin metal wires, and the second electrodes of the semiconductor chip and the inner terminals of the conductor portions may be connected via second thin metal wires having higher stiffness than the first thin metal wires.

Further, a plurality of semiconductor chips may be stacked, the electrodes of the semiconductor chip at the lowest level and the inner terminals of conductor portions may be connected via first thin metal wires, and the electrodes of the semiconductor chip at not lower than the second level and the inner terminals of the conductor portions may be connected via second thin metal wires having higher stiffness than the first thin metal wires.

Moreover, a plurality of semiconductor chips may be stacked, the electrodes of the semiconductor chip at the lowest level and the inner terminals of the conductor portions may be connected via first thin metal wires, the electrodes of the semiconductor chip at not lower than the second level and the inner terminals of the conductor portions may be connected via second thin metal wires having higher stiffness than the first thin metal wires, and some of the electrodes of the plurality of semiconductor chips may be connected via the second thin metal wires.

The thin metal wires at the lowest level have tops lower than the tops of the other thin metal wires. Circuit elements may be formed under the electrodes of the semiconductor chip, the electrodes being connected to the thin metal wires at the lowest level.

A method of manufacturing a semiconductor device of the present invention includes a first step of mounting, on a support, a semiconductor chip having a plurality of electrodes formed on a major surface of the semiconductor chip, a second step of connecting, via thin metal wires, the plurality of electrodes of the semiconductor chip mounted on the support and the inner terminals of a plurality of conductor portions arranged around the semiconductor chip, and a third step of sealing the semiconductor chip and the thin metal wires with resin, wherein in the second step, the electrodes and the inner terminals are connected via the thin metal wires having the lowest stiffness at the lowest level out of the plurality of vertically arranged thin metal wires, and then the electrodes and the inner terminals are connected via the thin metal wires having higher stiffness.

For example, it is possible to perform a first step of mounting, on a support, a semiconductor chip having first electrodes arranged in rows on the periphery of a major surface of the semiconductor chip and second electrodes arranged at least in a signal row closer to the center of the major surface than the first electrodes, a second step of connecting the first electrodes of the semiconductor chip and the inner terminals of a plurality of conductor portions around the semiconductor chip via first thin metal wires, and then connecting the second electrodes of the semiconductor chip and the inner terminals of the plurality of conductor portions via second thin metal wires having higher stiffness than the first thin metal wires, and a third step of sealing the semiconductor chip and the first and second thin metal wires with resin.

Further, it is possible to perform a first step of stacking and mounting, on a support, a plurality of semiconductor chips, each having a plurality of electrodes on the periphery of a major surface of the semiconductor chip, a second step of connecting the electrodes of the semiconductor chip at the lowest level and the inner terminals of a plurality of conductor portions around the semiconductor chip via first thin metal wires, and then connecting the electrodes of the semiconductor chip at not lower than the second level and the inner terminals of the plurality of conductor portions via second thin metal wires having higher stiffness than the first thin metal wires, and a third step of sealing the plurality of semiconductor chips and the first and second thin metal wires with resin.

Furthermore, it is possible to perform a first step of stacking and mounting, on a support, a plurality of semiconductor chips, each having a plurality of electrodes on the periphery of a major surface of the semiconductor chip, a second step of connecting the electrodes of the semiconductor chip at the lowest level and the inner terminals of a plurality of conductor portions around the semiconductor chip via first thin metal wires, thereafter connecting the electrodes of the semiconductor chip at not lower than the second level and the inner terminals of the plurality of conductor portions via second thin metal wires having higher stiffness than the first thin metal wires, and connecting some of the electrodes of the plurality of semiconductor chips via the second thin metal wires, and a third step of sealing the plurality of semiconductor chips and the first and second thin metal wires with resin.

Stiffness may vary between the thin metal wires at the lowest level and the other thin metal wires according to the compositions of metallic materials. The thin metal wires at the lowest level may be mainly made of gold and the other thin metal wires may be mainly made of copper. Alternatively, the thin metal wires at the lowest level and the other thin metal wires may be mainly made of gold, and the thin metal wires at the lowest level may have higher contents of gold than the other thin metal wires.

The plurality of conductor portions may be formed on the support for mounting the semiconductor chip. The support having the plurality of conductor portions is, for example, a wiring board. The plurality of conductor portions may be arranged around the support for mounting the semiconductor chip. For example, the plurality of conductor portions and the support are provided on a lead frame.

### BRIEF DESCRIPTION OF THE DRAWINGS

FIG. 1 is a process sectional view for explaining a method of manufacturing a semiconductor device according to an embodiment of the present invention;

FIG. 2 is a process sectional view for explaining a method of manufacturing a semiconductor device according to another embodiment of the present invention;

FIG. 3 is a sectional view showing a semiconductor device according to still another embodiment of the present invention;

FIG. 4 is a sectional view showing a semiconductor device according to still another embodiment of the present invention;

FIG. 5 is a sectional view showing a semiconductor device according to still another embodiment of the present invention;

FIG. 6 is a sectional view showing a semiconductor device according to still another embodiment of the present invention; and

FIG. 7 is a sectional view showing a conventional semiconductor device.

### DESCRIPTION OF THE EMBODIMENTS

The following will describe embodiments of the present invention in accordance with the accompanying drawings.

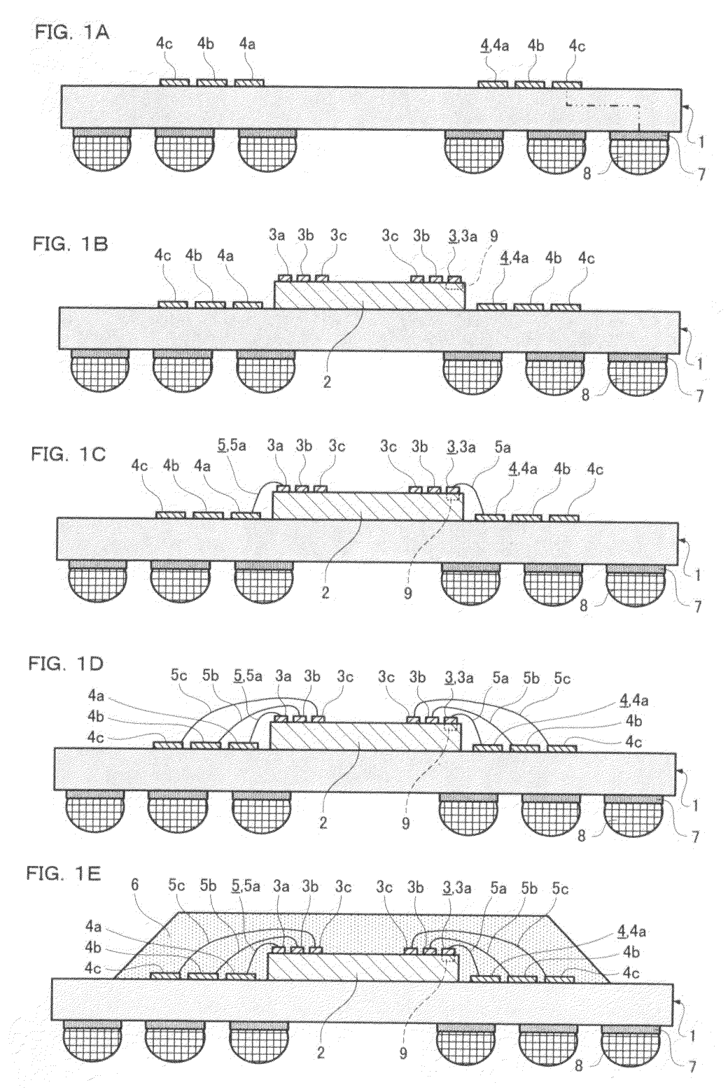

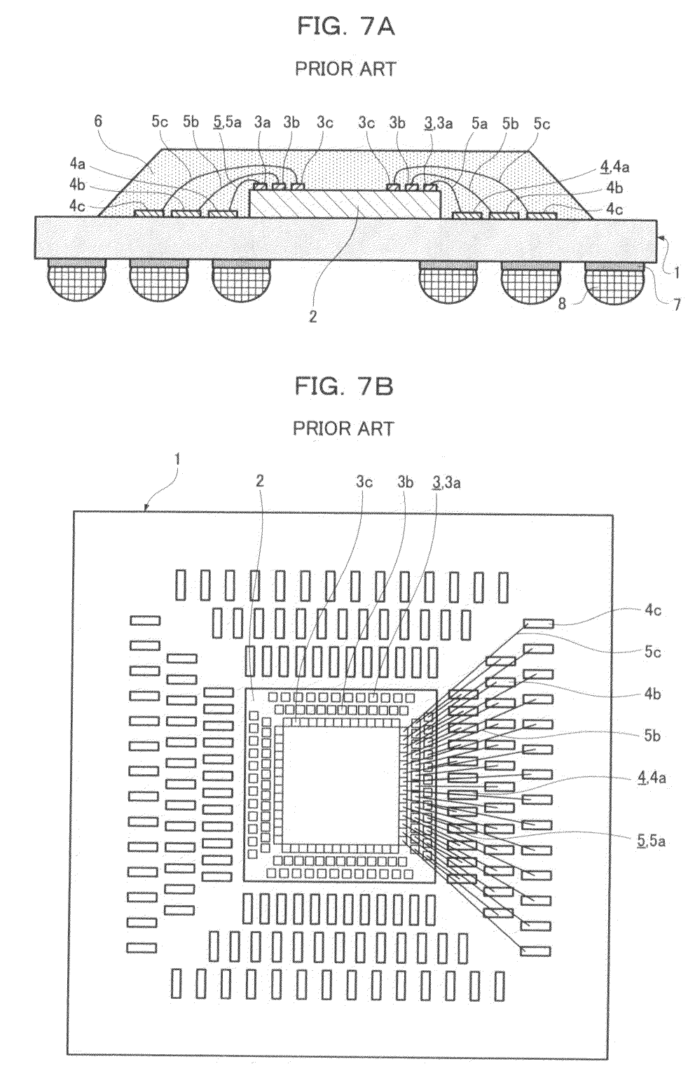

FIG. 1 shows a process for manufacturing a BGA package which is a semiconductor device according to an embodiment of the present invention. In the following explanation, the same members as the conventional semiconductor device of FIG. 7 are indicated by the same reference numerals.

First, a BGA substrate 1 (hereinafter, will be simply referred to as a substrate 1) shown in FIG. 1(A) is prepared. The substrate 1 is made of glass epoxy (or BT resin, polyimide, and the like) and has a thickness of about 0.05 mm to 1.0 mm. Conductor portions (indicated by virtual lines) including a wiring pattern and through holes are formed on the substrate 1. Internal electrodes 4 electrically connected through the conductor portions and external electrodes 7 to be connected to an external mounting substrate and the like are respectively formed on the chip mounting surface and the backside of the substrate 1. A substrate surface around the internal electrodes 4 and the external electrodes 7 is covered with an insulating layer (not shown) made of a solder resist and so on.

The internal electrodes 4 are arranged around a chip mounting area set at the center of the chip mounting surface and are spaced along the periphery of the area, and the internal electrodes 4 are arranged in multiple rows and are spaced in a direction from the center to the periphery of the chip mounting surface (see also FIG. 7). The internal electrodes 4 in the respective rows are denoted as 4a, 4b and 4c from the innermost row.

The internal electrodes 4 are formed thus in multiple rows because even when arranged with the minimum pitch, the internal electrodes 4 in a single row cannot respond to all the pins of the semiconductor chip. The internal electrodes 4 are generally formed with about 50-μm to 500-μm pitches, are mainly made of a material such as Cu, and have a thickness of 5 μm to 35 μm. An Au coating and the like having a thickness of about 0.01 μm to 5 μm is applied on the surfaces of the internal electrodes 4. External electrodes 3 as many as the internal electrodes 4 are formed of the same material as the internal electrodes 4 and are arranged so as to correspond to the internal electrodes 4.

Next, as shown in FIG. 1(B), a semiconductor chip 2 is fixed on the substrate 1. For this fixation, a thermosetting resin (not shown) such as epoxy and polyimide is disposed between the substrate 1 and the semiconductor chip 2.

The external electrodes 3 of the semiconductor chip 2 are arranged on the edge of a major surface of the semiconductor chip 2 and are spaced along the periphery of the major surface, and the external electrodes 3 are arranged in multiple rows and are spaced in a direction from the center to the periphery of the major surface. The external electrodes 3 in the respective rows are denoted as 3a, 3b and 3c from the outermost row.

The electrodes 3 are arranged thus in multiple rows because when the number of electrodes of the semiconductor chip 2 is increased (about 10 to 2000 pins according to the circuit size and so on), a required number of electrodes cannot be arranged in a signal row even with the minimum pitch. The electrodes 3 are generally made of a material such as AL, Au, and Cu. When the electrodes 3 are mainly made of AL, a small amount of Si, Cu and so on is added. The electrodes 3 are staggered or arranged in parallel. Under the electrodes 3a in the outermost row on the semiconductor chip 2, semiconductor elements such as a transistor and circuit elements 9 such as a wire are formed.

Next, as shown in FIG. 1(C), the electrodes 3a in the outermost row on the semiconductor chip 2 and the internal electrodes 4a in the innermost row on the substrate 1 are electrically connected via wires 5a by wire bonding. After that, as shown in FIG. 1(D), the electrodes 3b in the central row on the semiconductor chip 2 and the internal electrodes 4b in the central row on the substrate 1 are electrically connected via wires 5b. Thereafter, the electrodes 3c in the innermost row on the semiconductor chip 2 and the internal electrodes 4c in the outermost row on the substrate 1 are electrically connected via wires 5c. The wire bonding process shown in FIGS. 1(C) and 1(D) is normally performed while heat, ultrasonic waves, and a pressure are applied. The heating temperature is about 50° C. to 300° C., the ultrasonic output is about 10 mW to 300 mW, and the pressure is about 10 gf to 100 gf.

In this case, it is important that stiffness varies between the wires 5a (hereinafter, will be referred to as first wires 5a) connected to the electrodes 3a in the outermost row on the semiconductor chip 2 and the wires 5b and 5c (hereinafter, will be referred to as second wires 5b and 5c) connected to the electrodes 3b and 3c disposed inside the electrodes 3a. The second wires 5b and 5c have higher stiffness than the first wires 5a.

After completion of wire bonding, as shown in FIG. 1(E), a sealing resin 6 is formed on one side of the substrate 1 by transfer molding and the like so as to cover the semiconductor chip 2, the first wires 5a, and the second wires 5b and 5c, and then solder balls 8 are formed on the external electrodes 7 of the substrate 1. The BGA package is completed thus.

As described above, the second wires 5b and 5c have higher stiffness than the first wires 5a in the BGA package. This is because when connecting the electrodes 3a, 3b and 3c and the internal electrodes 4a, 4b and 4c in multiple rows, the wires 5a, 5b and 5c are likely to overlap one another at least in a part thereof in plan view, that is, the wires 5a, 5b and 5c are likely to be vertically arranged at least in a part thereof. This arrangement is hard to avoid.

Another reason is that the second wires 5b and 5c connected to the electrodes 3b and 3c close to the center of the semiconductor chip 2 have to be drawn at the joints to the electrodes 3b and 3c vertically with respect to the semiconductor chip 2 and form loops, so that the wires are increased in height and length.

Since the second wires 5b and 5c have relatively high stiffness, the shapes of the loops formed upon bonding can be easily controlled. Further, the loops are hardly deformed (distorted) after bonding and it is possible to suppress deformations caused by stresses generated by a resin flow during resin sealing. Thus a desired height and shape can be kept. The first wires 5a disposed at the lowest level and connected to the electrodes 3a in the outermost row on the semiconductor chip 2 have the lowest stiffness, so that the wires 5a can be reduced in height. It is thus possible to increase a distance between the first wires 5a and the second wires 5b and 5c at a higher level.

With this configuration, failures such as contact between the first wires 5a and the second wires 5b and 5c hardly occur, so that the yields increase. The second wires 5b and 5c are so small in height that the second wires 5b and 5c do not come into contact with the first wires 5a. Thus the overall device can be reduced in thickness.

Further, during bonding with the first wires 5a having low stiffness, just a light load is applied to the electrodes 3a. Thus as described above, the circuit elements 9 disposed under the electrodes 3a do not cause damage, so that reliability can be ensured. Reversely, since the first wires 5a have low stiffness, the circuit elements 9 can be also formed on the periphery of the semiconductor chip 2. It is therefore possible to reduce the size of the semiconductor chip 2 and the cost.

For this configuration, the wires are made of different materials. For example, the first wires 5a at the lowest level are made of Au and the second wires 5b and 5c at a higher level than the first wires 5a are made of Cu. Further, the contents vary between the wires. For example, the first wires 5a are Au wires having high contents of gold (not lower than 99.99 mass %) and the second wires 5b and 5c are Au wires having low contents of gold (about 99.90 mass % to 99.00 mass %). By using Cu or Au of a low impurity, it is possible to reduce the usage amount of Au which is an expensive material, thereby reducing the cost.

Instead of the different compositions between the first wires 5a and the second wires 5b and 5c, the stiffness may be varied by different diameters. Generally, the wires are about 12 μm to 30 μm in diameter and a proper diameter can be selected. The first wires 5a at the lowest level may include wires not overlapping the second wires 5b and 5c in plan view.

As described above, after the electrodes 3a in the outermost row on the semiconductor chip 2 are connected via the first wires 5a, the electrodes 3b and 3c inside the electrodes 3a are connected via the second wires 5b and 5c. For these connections, it is efficient that a wire bonder for the first wires 5a is different from a wire bonder for the second wires 5b and 5c.

In the above explanation, stiffness varies between two groups of the first wires 5a and the second wires 5b and 5c. Stiffness may increase with the levels of the wires, that is, the stiffness of the wire 5a<the stiffness of the wire 5b<the stiffness of the wire 5c may be set.

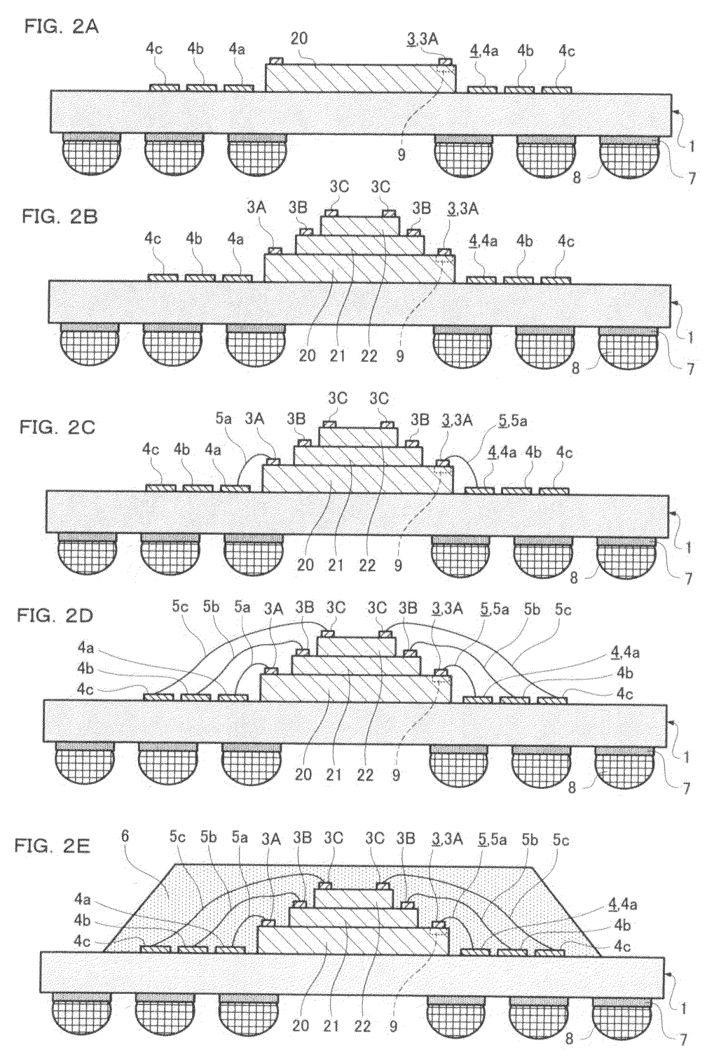

FIG. 2 shows a process for manufacturing a BGA package as a semiconductor device according to another embodiment of the present invention.

As shown in FIG. 2(A), a substrate 1 similar to the substrate 1 of the above embodiment is prepared. After that, a first semiconductor chip 20 having electrodes 3A formed on the edge of the chip is fixed on the substrate 1, and as shown in FIG. 2(B), a second semiconductor chip 21 having electrodes 3B formed on the edge of the chip and a third semiconductor chip 22 having electrodes 3C formed on the edge of the chip are stacked and fixed on the first semiconductor chip 20. For this fixation, a thermosetting resin is used. The electrodes 3A, 3B and 3C are provided as many as the electrodes 3a, 3b and 3c and the configurations of the electrodes 3A, 3B and 3C are identical to the electrodes 3a, 3b and 3c. Under the electrodes 3A of the first semiconductor chip 20, semiconductor elements such as a transistor and circuit elements 9 such as a wire are formed.

Next, as shown in FIG. 2(C), the electrodes 3A of the first semiconductor chip 20 and internal electrodes 4a in the innermost row on the substrate 1 are electrically connected via wires 5a by wire bonding. After that, as shown in FIG. 2(D), the electrodes 3B of the second semiconductor chip 21 and internal electrodes 4b in the central row on the substrate 1 are electrically connected via wires 5b. Thereafter, the electrodes 3C of the third semiconductor chip 22 and internal electrodes 4c in the outermost row on the substrate 1 are electrically connected via wires 5c. The wire bonding process shown in FIGS. 2(C) and 2(D) is normally performed while heat, ultrasonic waves, and a pressure are applied in the foregoing manner.

In this case, it is important that stiffness varies between the wires 5a (hereinafter, will be referred to as first wires 5a) connected to the electrodes 3A of the first semiconductor chip 20 and the wires 5b and 5c (hereinafter, will be referred to as second wires 5b and 5c) connected to the electrodes 3B and 3C of the second and third semiconductor chips 21 and 22. The second wires 5b and 5c have higher stiffness than the first wires 5a.

After completion of wire bonding, as shown in FIG. 2(E), a sealing resin 6 is formed on one side of the substrate 1 by transfer molding and the like so as to cover the semiconductor chips 20, 21 and 22 and the wires 5a, 5b and 5c, and then solder balls 8 are formed on external electrodes 7 of the substrate 1. The BGA package is completed thus.

Also in this BGA package, when connecting the electrodes 3A, 3B and 3C of the semiconductor chips 20, 21 and 22 stacked at multiple levels and the internal electrodes 4a, 4b and 4c, the wires 5a, 5b and 5c are likely to vertically overlap one another at least in a part thereof in plan view. This arrangement is hard to avoid. Therefore, the second wires 5b and 5c connected to the electrodes 3B and 3C have higher hardness than the first wires 5a, the electrodes 3B and 3C being disposed on the semiconductor chips 21 and 22 at a higher level and close to the center of the device. With this configuration, the same effect as the BGA package of FIG. 1 can be obtained.

Regarding the second wires 5b and 5c, the shapes of the loops formed upon bonding can be easily controlled. Further, the loops are hardly deformed (distorted) after bonding and it is possible to suppress deformations caused by stresses generated by a resin flow during resin sealing. Thus a desired height and shape can be kept. Since the first wires 5a at the lowest level can be reduced in height, it is possible to increase a distance between the first wires 5a and the second wires 5b and 5c at a higher level. With this configuration, failures such as contact between the first wires 5a and the second wires 5b and 5c hardly occur, so that the yields increase. The second wires 5b and 5c are so small in height that the second wires 5b and 5c do not come into contact with the first wires 5a. Thus the overall device can be reduced in thickness.

Further, during bonding with the first wires 5a having low stiffness, just a light load is applied to the electrodes 3A. Thus the circuit elements 9 disposed under the electrodes 3A do not cause damage, so that reliability can be ensured. Reversely, since the first wires 5a have low stiffness, the circuit elements 9 can be also formed on the periphery of the semiconductor chip 20. It is therefore possible to reduce the size of the semiconductor chip 20 and the cost.

The first wires 5a and the second wires 5b and 5c can be similar to the wires of the BGA package shown in FIG. 1. By using Cu or Au of a low impurity, it is possible to reduce the usage amount of Au which is an expensive material, thereby reducing the cost. Moreover, the stiffness of the wire 5a<the stiffness of the wire 5b<the stiffness of the wire 5c may be set. Moreover, the order of bonding and the device may be similar to the order and device in the explanation of the BGA package shown in FIG. 1.

Although the semiconductor chip 20 at the lowest level is illustrated with the largest size, the positions and sizes of the stacked semiconductor chips are not limited. For example, when the semiconductor chip 20 at the lowest level is not wire bonded, the semiconductor chip 20 may be smaller in size than the other semiconductor chips 21 and 22.

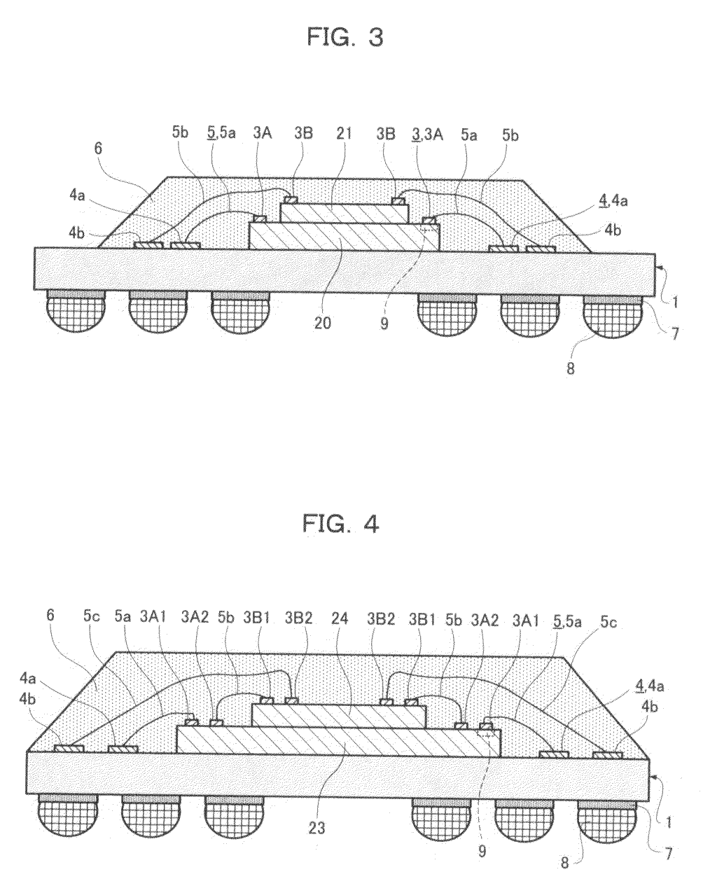

In the above explanation, the number of stacked semiconductor chips is three. The above configuration can be realized by at least two semiconductor chips and the same effect can be obtained. FIG. 3 shows a BGA package in which the two semiconductor chips 20 and 21 are stacked.

FIG. 4 shows the configuration of a BGA package as a semiconductor device according to still another embodiment of the present invention. In this BGA package, a first semiconductor chip 23 and a second semiconductor chip 24 are stacked and fixed on a substrate 1. The explanation of the same points as the BGA package of FIG. 2 is omitted.

A plurality of electrodes 3 of the first semiconductor chip 23 are arranged on the edge of a major surface of the semiconductor chip and are spaced along the periphery of the major surface, and the electrodes 3 are arranged in multiple rows and are spaced in a direction from the center to the periphery of the major surface. The electrodes 3 are denoted as 3A1 and 3A2 from the peripheral side. A plurality of electrodes 3 on the second semiconductor chip 24 are also similarly arranged in multiple rows on the edge of a major surface of the semiconductor chip. The electrodes 3 are denoted as 3B1 and 3B2 from the peripheral side.

The electrodes 3A1 in the outer row on the first semiconductor chip 23 and internal electrodes 4a in the inner row on the substrate 1 are electrically connected via wires 5a by wire bonding. The electrodes 3A2 in the inner row on the first semiconductor chip 23 and the electrodes 3B1 in the outer row of the second semiconductor chip 24 are connected via wires 5b. The electrodes 3A2 and the electrodes 3B1 are connected to electrically connect the first semiconductor chip 23 and the second semiconductor chip 24 in a space-saving manner without connection via the substrate 1. The electrodes 3B2 in the inner row on the second semiconductor chip 24 and internal electrodes 4b in the outer row on the substrate 1 are connected via wires 5c of the same kind as the wires 5b.

The wires 5b and 5c (hereinafter, will be referred to as second wires 5b and 5c) have higher stiffness than the wires 5a (hereinafter, will be referred to as first wires 5a). The first wires 5a connect the electrodes 3A1 of the first semiconductor chip 23 and the internal electrodes 4a, the second wires 5b connect the electrodes 3A2 and 3B1, and the second wires 5c connect the electrodes 3B2 and the internal electrodes 4b.

Also in this BGA package, the second wires 5b and 5c connected to the electrodes 3B2 and 3B1 have higher stiffness than the first wires 5a connected to the electrodes 3A1 of the semiconductor chip 23 at a lower level, the electrodes 3B2 and 3B1 being disposed on the semiconductor chip 24 at a higher level and close to the center of the device. In other words, the second wires 5b and 5c at a higher level have higher stiffness than the first wires 5a at the lowest level. Thus the same effect as the BGA packages of FIGS. 1 and 2 can be obtained.

The usable first wires 5a and second wires 5b and 5c are similar to the wires of the BGA package shown in FIG. 1. Since the second wires 5b are not likely to overlap the first wires 5a, the second wires 5b do not always have to have higher stiffness than the first wires 5a and the same wires as the first wires 5a can be used as the second wires 5b. As a matter of course, the stiffness of the wire 5a<the stiffness of the wire 5b<the stiffness of the wire 5c may be set.

Although the semiconductor chip 23 at a lower level is illustrated with a larger size, the positions and sizes of the stacked semiconductor chips are not limited. For example, when the semiconductor chip 23 at a lower level is not wire bonded, the semiconductor chip 23 may be smaller in size than the semiconductor chip 24.

The number of stacked semiconductor is two in the above explanation. The above configuration can be realized by at least two semiconductor chips and the same effect can be obtained.

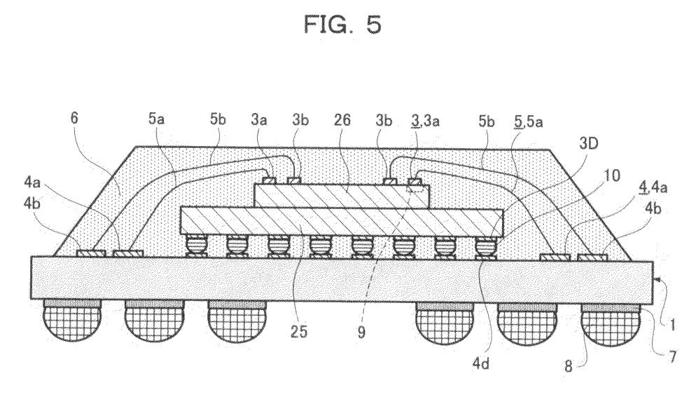

FIG. 5 shows the configuration of a BGA package as a semiconductor device according to still another embodiment of the present invention. In this BGA package, a first semiconductor chip 25 and a second semiconductor chip 26 are stacked and mounted on a substrate 1.

The first semiconductor chip 25 has electrodes 3D formed in a grid-like fashion on a major surface and solder balls 10 formed on the electrodes 3. The solder balls 10 are bonded to internal electrodes 4d formed in a chip mounting area of the substrate 1.

The second semiconductor chip 26 is fixed on the first semiconductor chip 25. A plurality of electrodes 3 of the second semiconductor chip 26 are arranged on the edge of a major surface of the semiconductor chip and are spaced along the periphery of the major surface, and the electrodes 3 are arranged in multiple rows and are spaced in a direction from the center to the periphery of the major surface. The electrodes 3 are denoted as 3a and 3b from the peripheral side.

The electrodes 3a in the outer row on the second semiconductor chip 26 and internal electrodes 4a in the inner row on the substrate 1 are electrically connected via wires 5a by wire bonding. The electrodes 3b in the inner row on the second semiconductor chip 26 and internal electrodes 4b in the outer row on the substrate 1 are connected via wires 5b. The wires 5b (hereinafter, will be referred to as second wires 5b) have higher stiffness than the wires 5a (hereinafter, will be referred to as first wires 5a).

Also in this BGA package, the first wires 5a disposed at the lowest level and connected to the electrodes 3a in the outermost row on the second semiconductor chip 26 have the lowest stiffness and the second wires 5b at a higher level have higher stiffness. Thus the same effect as the BGA package of FIG. 1 can be obtained.

The usable first wires 5a and second wires 5b and the order of bonding are similar to the wires and the order of the BGA package shown in FIG. 1.

Although the semiconductor chip 25 at a lower level is illustrated with a larger size, the positions and sizes of the stacked semiconductor chips are not limited. For example, the semiconductor chip 25 at a lower level may be smaller in size than the semiconductor chip 26.

In the above explanation, the number of stacked semiconductor chips is two. The above configuration can be realized by at least two semiconductor chips and the same effect can be obtained.

The BGA package is, in the above explanation, a single package using the substrate 1. It is needless to say that a plurality of connected BGA packages may be manufactured using substrates shaped like strips and the like having a plurality of mounting areas, and then the BGA packages may be separated from one another. The foregoing configurations are also applicable to QFP packages and other kinds of packages with the same effect.

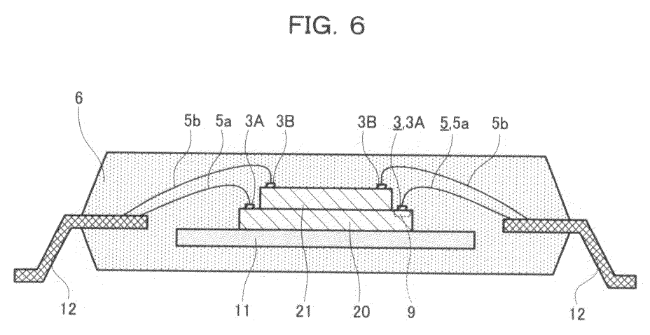

FIG. 6 shows a QFP package. The same members as the BGA package of FIG. 2 are indicated by the same reference numerals and the explanation thereof is omitted. Reference numeral 11 denotes a die pad acting as a support of semiconductor chips 20 and 21. Reference numeral 12 denotes a plurality of leads arranged around the die pad. The die pad 11 and the leads 12 are connected in a lead frame used in a manufacturing process and thus are handled as a single unit.

Also in this QFP package, second wires 5b at a higher level have higher stiffness than first wires 5a at the lowest level. Thus the same effect as the BGA packages of FIGS. 1 and 2 can be obtained.

As described above, of a plurality of thin metal wires vertically arranged to connect a plurality of electrodes on a semiconductor chip and the inner terminals of a plurality of conductor portions arranged around the semiconductor chip in the semiconductor device of the present invention, the thin metal wires at the lowest level have the lowest stiffness and the thin metal wires at a higher level have higher stiffness. Thus it is possible to prevent contact between the thin metal wires and improve the yields. By using Cu and Au of a low impurity as the thin metal wires having higher stiffness, it is possible to reduce the usage amount of Au as compared with the prior art, reducing the cost. The present invention is particularly useful for manufacturing small semiconductor devices mounted with multiple pins in electronic equipment such as mobile communications equipment.

What is claimed is:

1. A semiconductor device in which a plurality of electrodes formed on a major surface of a semiconductor chip and inner terminals of a plurality of conductor portions arranged around the semiconductor chip are electrically connected via thin metal wires and the semiconductor chip and the thin metal wires are sealed with resin, wherein of the plurality of thin metal wires vertically arranged to connect the electrodes of the semiconductor chip and the inner terminals of the conductor portions, the thin metal wires at a lowest level have lowest stiffness.

2. The semiconductor device according to claim 1, wherein the semiconductor chip has first electrodes arranged in rows on a periphery of the major surface and second electrodes arranged at least in a single row closer to a center of the major surface than the first electrodes, the first electrodes of the semiconductor chip and the inner terminals of the conductor portions are connected via first thin metal wires, and the second electrodes of the semiconductor chip and the inner terminals of the conductor portions are connected via second thin metal wires having higher stiffness than the first thin metal wires.

3. The semiconductor device according to claim 1, wherein a plurality of semiconductor chips are stacked, electrodes of the semiconductor chip at the lowest level and the inner terminals of the conductor portions are connected via first thin metal wires, and electrodes of the semiconductor chip at not lower than a second level and the inner terminals of the conductor portions are connected via second thin metal wires having higher stiffness than the first thin metal wires.

4. The semiconductor device according to claim 1, wherein a plurality of semiconductor chips are stacked, electrodes of the semiconductor chip at the lowest level and the inner terminals of the conductor portions are connected via first thin metal wires, electrodes of the semiconductor chip at not lower than a second level and the inner terminals of the conductor portions are connected via second thin metal wires having higher stiffness than the first thin metal wires, and some of the electrodes of the plurality of semiconductor chips are connected via the second thin metal wires.

5. The semiconductor device according to claim 1, wherein stiffness varies between the thin metal wires at the lowest level and the other thin metal wires according to compositions of metallic materials.

6. The semiconductor device according to claim 5, wherein the thin metal wires at the lowest level are mainly made of gold and the other thin metal wires are mainly made of copper.

7. The semiconductor device according to claim 5, wherein the thin metal wires at the lowest level and the other thin metal wires are mainly made of gold, and the thin metal wires at the lowest level have higher contents of gold than the other thin metal wires.

8. The semiconductor device according to claim 1, wherein the thin metal wires at the lowest level have tops lower than the tops of the other thin metal wires.

9. The semiconductor device according to claim 1, further comprising circuit elements formed under the electrodes of the semiconductor chip, the electrodes being connected to the thin metal wires at the lowest level.

10. The semiconductor device according to claim 1, wherein the plurality of conductor portions are formed on a support for mounting the semiconductor chip.

11. The semiconductor device according to claim 1, wherein the plurality of conductor portions are arranged around a support for mounting the semiconductor chip.

12. A method of manufacturing a semiconductor device, comprising:
a first step of mounting, on a support, a semiconductor chip having a plurality of electrodes formed on a major surface of the semiconductor chip;
a second step of connecting, via thin metal wires, the plurality of electrodes of the semiconductor chip mounted on the support and inner terminals of a plurality of conductor portions arranged around the semiconductor chip; and
a third step of sealing the semiconductor chip and the thin metal wires with resin,
wherein in the second step, the electrodes and the inner terminals are connected via the thin metal wires having lowest stiffness at a lowest level out of the plurality of vertically arranged thin metal wires, and then the other electrodes and inner terminals are connected via the thin metal wires having higher stiffness.

13. The method of manufacturing a semiconductor device according to claim 12, further performing:
a first step of mounting, on the support, the semiconductor chip having first electrodes arranged in rows on a periphery of a major surface of the semiconductor chip and second electrodes arranged at least in a signal row closer to a center of the major surface than the first electrodes;
a second step of connecting the first electrodes of the semiconductor chip and the inner terminals of the plurality of conductor portions around the semiconductor chip via first thin metal wires, and then connecting the second electrodes of the semiconductor chip and the inner terminals of the plurality of conductor portions via second thin metal wires having higher stiffness than the first thin metal wires; and
a third step of sealing the semiconductor chip and the first and second thin metal wires with resin.

14. The method of manufacturing a semiconductor device according to claim 12, further performing:
a first step of stacking and mounting, on the support, a plurality of semiconductor chips, each having a plurality of electrodes on a periphery of a major surface of the semiconductor chip;
a second step of connecting the electrodes of the semiconductor chip at a lowest level and the inner terminals of the plurality of conductor portions around the semiconductor chip via first thin metal wires, and then connecting the electrodes of the semiconductor chip at not lower than a second level and the inner terminals of the plurality of conductor portions via second thin metal wires having higher stiffness than the first thin metal wires; and
a third step of sealing the plurality of semiconductor chips and the first and second thin metal wires with resin.

15. The method of manufacturing a semiconductor device according to claim 12, further performing:
a first step of stacking and mounting, on the support, a plurality of semiconductor chips, each having a plurality of electrodes on a periphery of a major surface of the semiconductor chip;
a second step of connecting the electrodes of the semiconductor chip at a lowest level and the inner terminals of the plurality of conductor portions around the semiconductor chip via first thin metal wires, thereafter connecting the electrodes of the semiconductor chip at not lower than a second level and the inner terminals of the plurality of conductor portions via second thin metal wires having higher stiffness than the first thin metal wires, and connecting some of the electrodes of the plurality of semiconductor chips via the second thin metal wires; and
a third step of sealing the plurality of semiconductor chips and the first and second thin metal wires with resin.

16. The method of manufacturing a semiconductor device according to claim 12, wherein stiffness varies between the thin metal wires at the lowest level and the other thin metal wires according to compositions of metallic materials.

17. The method of manufacturing a semiconductor device according to claim 12, wherein the thin metal wires at the lowest level are mainly made of gold and the other thin metal wires are mainly made of copper.

18. The method of manufacturing a semiconductor device according to claim 12, wherein the thin metal wires at the lowest level and the other thin metal wires are mainly made of gold, and the thin metal wires at the lowest level have higher contents of gold than the other thin metal wires.

19. The method of manufacturing a semiconductor device according to claim 12, wherein the plurality of conductor portions are formed on the support for mounting the semiconductor chip.

20. The method of manufacturing a semiconductor device according to claim 12, wherein the plurality of conductor portions are arranged around the support for mounting the semiconductor chip.
